(19) United States
(12) Patent Application Publication
(10) Pub. No.: US 2026/0206163 A1
(43) Pub. Date: Jul. 16, 2026

(54) EXPANSION CARD CLAMPING APPARATUS

(71) Applicant: Aivres Systems Inc., Fremont, CA (US)

(72) Inventor: Chiaming CHANG, Taoyuan (TW)

(21) Appl. No.: 19/458,653

(22) Filed: Jan. 23, 2026

(51) Int. Cl. H05K 7/14

(52) U.S. Cl. CPC H05K 7/1405; H05K 7/1408; H05K 7/1415; H05K 7/1418

(57) ABSTRACT

An expansion card clamping apparatus secures multiple expansion cards to a chassis without tools. A frame mounted to the chassis includes a row of card receiving openings and an upper support ledge extending along the openings to support bracket portions of the cards. A clamping bracket assembly is coupled to the frame and pivots as a unit between an open position and a closed position. The clamping bracket assembly includes a clamping bar extending along the upper support ledge and a handle for pivoting the clamping bracket assembly. In the closed position, the clamping bar simultaneously clamps the bracket portions of the expansion cards against the upper support ledge. In the open position, the expansion cards can be inserted into or removed from the card receiving openings.

### TECHNICAL FIELD

The present disclosure relates generally to mechanical structures for electronic equipment, and more particularly to a tool-less expansion card clamping apparatus for securing expansion cards, such as PCI Express (PCIe) cards, within a server or other electronic device chassis.

### BACKGROUND

Servers and other information processing devices commonly include expansion slots on a motherboard for receiving expansion cards, for example PCI Express (PCIe) cards. Each expansion card typically has a bracket portion that is aligned with an opening in a chassis wall, so that external connectors on the card are accessible from outside the chassis.

In conventional designs, each expansion card is individually secured to the chassis by a screw that passes through the bracket portion of the expansion card and into a corresponding threaded hole in the chassis or a mounting bar. To install or replace a card, a user must align the card in the slot, hold the bracket portion in place, and then insert and tighten the screw with a screwdriver. To remove or replace the card, the screw must be loosened and removed before the card can be taken out.

This screw-based structure has several drawbacks. First, the user must use a separate tool, such as a screwdriver, which can be inconvenient in field maintenance or data center environments. Second, when multiple expansion cards are installed or replaced at the same time, the user must repeat the screw operation for each individual card, which is time consuming and labor intensive. Third, the screw operation typically requires a certain amount of working space to access the screws using the screwdriver, which may not be available in high-density rack installations where access is limited. These issues become more pronounced as the number of expansion cards in a system increases.

Accordingly, there is a need for an improved expansion card clamping apparatus that allows expansion cards to be quickly installed, removed, or replaced without tools, that requires only a small operating space, and that can simultaneously secure multiple expansion cards in a simple and reliable manner.

### SUMMARY

Disclosed embodiments relate to mechanical apparatuses, systems, and methods for securing expansion cards in a chassis.

In one general aspect, an expansion card clamping apparatus may include a frame having one or more card-receiving openings positioned to receive one or more expansion cards, and an upper support ledge covering and extending along the one or more card-receiving openings and configured to support bracket portions of the one or more expansion cards in a fixed position relative to a chassis. The expansion card clamping apparatus may also include a clamping bracket assembly coupled to the frame and configured to pivot as a unit relative to the frame between a closed position and an open position. The clamping bracket assembly may include a clamping bar extending along the upper support ledge of the frame and positioned to overlie the bracket portions of the one or more expansion cards, and a handle configured to pivot the clamping bracket assembly between the open position and the closed position. When the clamping bracket assembly is in the open position, the one or more expansion cards are insertable into, or removable from, the one or more card-receiving openings. When the clamping bracket assembly is in the closed position, the clamping bar simultaneously clamps the bracket portions of the one or more expansion cards against the upper support ledge to secure the one or more expansion cards to the chassis. Other embodiments of this aspect include corresponding computer systems, apparatus, and computer programs recorded on one or more computer storage devices, each configured to perform the actions of the methods.

Implementations may include one or more of the following features. The expansion card clamping apparatus may include a latch structure having a first latch portion on the frame and a second latch portion on the clamping bracket assembly, the latch structure being configured to releasably retain the clamping bracket assembly in the closed position. The first latch portion may include a resilient latch arm mounted on the frame, and the second latch portion may include a latch projection formed on the handle. The resilient latch arm may include a metal spring plate having an engagement edge, and the latch projection may be configured to deflect the metal spring plate as the handle moves between the open position and the closed position and to engage the engagement edge when the clamping bracket assembly is in the closed position. The expansion card clamping apparatus may include a detent structure having a ball and a spring arranged on the frame and configured to provide tactile feedback when the clamping bracket assembly reaches the closed position. The expansion card clamping apparatus may include a clamping biasing member configured to urge the clamping bracket assembly toward the closed position. The clamping biasing member may include a compression spring arranged between the clamping bar and at least one of the frame and the chassis. The expansion card clamping apparatus may include an extension spring coupled to the handle and configured to bias the handle toward a position corresponding to the closed position of the clamping bracket assembly. The clamping bracket assembly may include a pair of side arms extending from opposite ends of the clamping bar, and the clamping bracket assembly may be pivotably coupled to the frame. The clamping bar may have a non-planar contact profile including a plurality of alternating raised and recessed portions configured to contact top edges of the bracket portions at a plurality of spaced locations along the one or more card-receiving openings. The frame may be configured to be fixed to a side of the chassis. The expansion card clamping apparatus may include an alignment pin connected to the clamping bracket assembly and a locating hole formed in the chassis or the frame, wherein the alignment pin enters the locating hole when the clamping bracket assembly is in the closed position. A guide ramp feature may be formed adjacent to the locating hole, and the alignment pin may be configured to ride along the guide ramp as the clamping bracket assembly pivots from the open position toward the closed position. The handle may be configured to be manually grasped and operated by a user to move the clamping bracket assembly between the open position and the closed position without use of a separate tool. The one or more expansion cards may include Peripheral Component Interconnect Express (PCIe) cards, and the clamping bar may be dimensioned to span bracket portions of at least two of the PCIe cards. A length of the clamping bar and a length of the upper support ledge may be selected based on a number of the one or more card-receiving openings, such that the expansion card clamping apparatus is configurable to secure different numbers of expansion cards by changing the lengths of the clamping bar and the upper support ledge. The frame may be configured to receive a plurality of clamping bracket assemblies spaced along the one or more card-receiving openings to form a plurality of independently operable clamping zones. Implementations of the described techniques may include hardware, a method or process, or a computer tangible medium.

In one general aspect, a method may include installing an expansion card clamping apparatus having (1) a frame having one or more card-receiving openings positioned to receive one or more expansion cards and an upper support ledge covering and extending along the one or more card-receiving openings, and (2) a clamping bracket assembly coupled to the frame and configured to pivot as a unit relative to the frame between a closed position and an open position, the clamping bracket assembly having a clamping bar extending along the upper support ledge of the frame and a handle configured to pivot the clamping bracket assembly between the open position and the closed position. The method may also include pivoting the clamping bracket assembly relative to the frame by operating the handle from the closed position to the open position such that the clamping bar is moved away from the upper support ledge. The method may further include inserting the one or more expansion cards into the one or more card- receiving openings such that bracket portions of the one or more expansion cards are supported by the upper support ledge. The method may also include pivoting the clamping bracket assembly relative to the frame by operating the handle from the open position to the closed position such that the clamping bar simultaneously clamps the bracket portions of the one or more expansion cards against the upper support ledge to secure the one or more expansion cards to the chassis. Other embodiments of this aspect include corresponding computer systems, apparatus, and computer programs recorded on one or more computer storage devices, each configured to perform the actions of the methods.

Implementations may include one or more of the following features. Pivoting the clamping bracket assembly from the open position to the closed position may further include engaging a latch structure having a first latch portion on the frame and a second latch portion on the clamping bracket assembly to releasably retain the clamping bracket assembly in the closed position. Operating the handle to pivot the clamping bracket assembly between the open position and the closed position may include manually grasping and moving the handle without use of a separate tool. Implementations of the described techniques may include hardware, a method or process, or a computer tangible medium.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates, for comparison, a conventional screw-based arrangement for securing PCIe cards in a server chassis and an example server including an expansion card clamping apparatus, in accordance with some embodiments.

FIG. 2 illustrates perspective views of an example expansion card clamping apparatus mounted at the front of a server chassis, in accordance with some embodiments.

FIG. 3A illustrates a detailed view of a frame of the apparatus, including a row of card receiving openings and an upper support ledge for supporting bracket portions of multiple expansion cards, in accordance with some embodiments.

FIG. 3B illustrates additional views of the frame, including a guide ramp feature that assists an alignment pin in entering a locating hole in the chassis, in accordance with some embodiments.

FIG. 4A illustrates an exploded view of a clamping bracket assembly, in accordance with some embodiments.

FIG. 4B illustrates the clamping bracket assembly and its component parts,, in accordance with some embodiments.

FIG. 5 illustrates an example sequence of user operations for pulling a handle to unlock, rotating the clamping bracket assembly to an open position, installing PCIe cards, and pushing the clamping bracket assembly back to secure the PCIe cards, in accordance with some embodiments.

FIG. 6 illustrates an example unlocking operation in which a boss feature on the handle pushes a spring latch plate to disengage the clamping bracket assembly from the frame, in accordance with some embodiments.

FIG. 7 illustrates an example interaction of an extension spring and a compression spring that causes the handle and clamping bar to return to their home positions and generates a downward clamping force, in accordance with some embodiments.

FIG. 8 illustrates example movement of the clamping bracket assembly within a slot, including cooperation of the guide ramp feature and alignment pin with a locating hole and a ball pin feature that positively locates the handle in its open and closed positions, in accordance with some embodiments.

FIG. 9A-9D illustrate another embodiment of the expansion card clamping apparatus, in accordance with some embodiments.

FIG. 10 illustrates an example flow diagram of a method for securing a plurality of expansion cards to a chassis using the expansion card clamping apparatus, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word "comprise" and variations thereof, such as, "comprises" and "comprising" are to be construed in an open, inclusive sense, that is as "including, but not limited to." Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms "a," "an" and "the" include plural referents unless the context clearly dictates otherwise.

Reference throughout this specification to "one embodiment" or "an embodiment" means that a particular feature, structure or characteristic described in connection with the embodiment is included in at least one embodiment of the present disclosure. Thus, the appearances of the phrases "in one embodiment" or "in an embodiment" in various places throughout this specification are not necessarily all referring to the same embodiment, but may be in some instances. Furthermore, the particular features, structures, or characteristics may be combined in any suitable manner in one or more embodiments.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term "invention" merely for convenience and without intending to voluntarily limit the scope of this application to any single disclosure or concept if more than one is, in fact, disclosed.

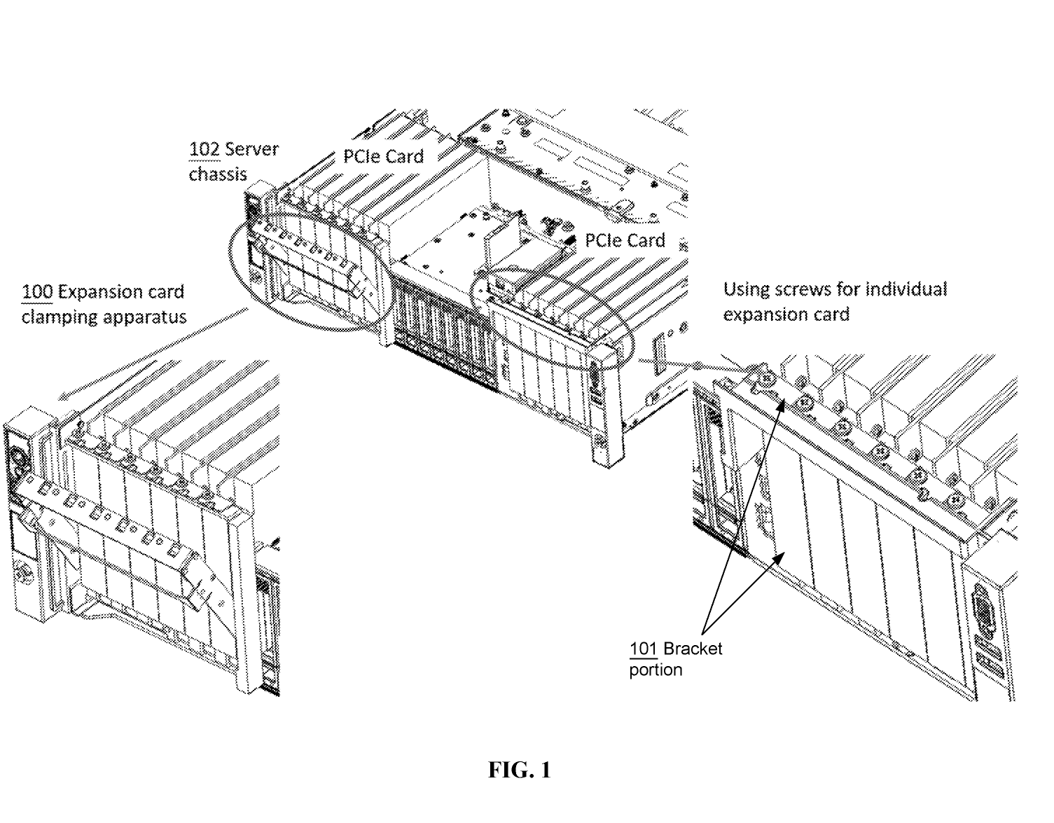

FIG. 1 illustrates, for comparison, a server chassis 102 having, on one side, a screw- based arrangement for securing PCIe expansion cards and, on the other side, an expansion card clamping apparatus 100, in accordance with some embodiments. On the screw-based arrangement side, a plurality of PCIe expansion cards are received in respective slots of the motherboard, and each card includes a bracket portion 101 aligned with a corresponding opening of the chassis. Each bracket portion 101 is individually fastened to the chassis by a screw. To install or remove a card, a user must access the front of the chassis, hold the bracket portion in place, and tighten or loosen the associated screw with a screwdriver. When multiple cards are installed or replaced, this operation must be repeated card-by-card, which requires a separate tool, sufficient working space in front of the chassis, and a relatively large amount of time and effort.

On the opposite side of FIG. 1, the server chassis 102 is shown equipped with an expansion card clamping apparatus 100 including a frame and a clamping bracket assembly with a clamping bar and a handle (more details below). The frame defines a row of card receiving openings and an upper support ledge that supports bracket portions of a row of PCIe cards. The clamping bracket assembly is pivotable relative to the frame between an open position and a closed position. In use, a user operates the handle to pivot the clamping bracket assembly to the open position, insert or remove a row of PCIe cards, and then pivot the clamping bracket assembly back to the closed position so that the clamping bar simultaneously clamps the bracket portions of the row of PCIe cards against the upper support ledge without using individual screws.

The conventional arrangement and the expansion card clamping apparatus 100 are shown together in FIG. 1 for illustration and comparison only; in practice, a given chassis may employ one or more of the expansion card clamping apparatus 100, or any suitable combination of the expansion card clamping apparatus 100 and the conventional screw-based structure.

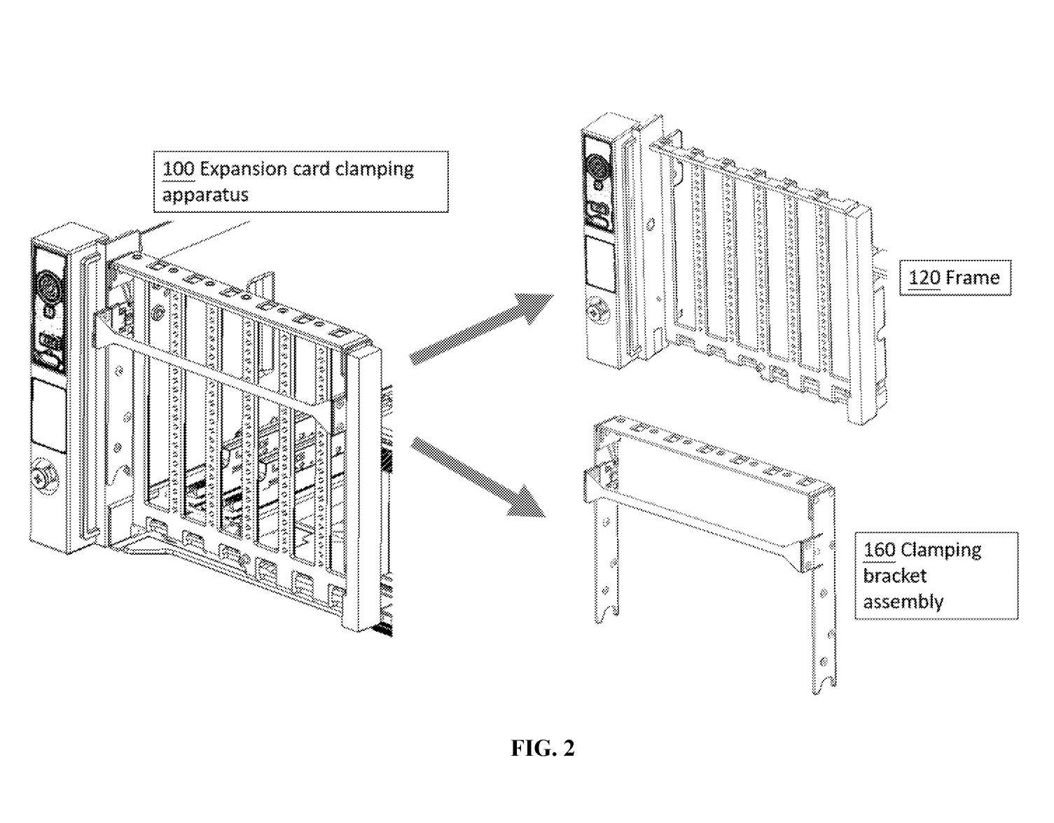

FIG. 2 illustrates perspective views of an example expansion card clamping apparatus 100 mounted at the front of a server chassis, in accordance with some embodiments. In the left view, the expansion card clamping apparatus 100 is shown in an assembled state at the front opening of the chassis. The expansion card clamping apparatus 100 generally spans a row of expansion card positions and is arranged so that bracket portions of a plurality of expansion cards can be supported and clamped at the front side of the chassis. This current invention also works with single expansion card use cases, it is just more efficient for clamping multiple expansion cards at the same time.

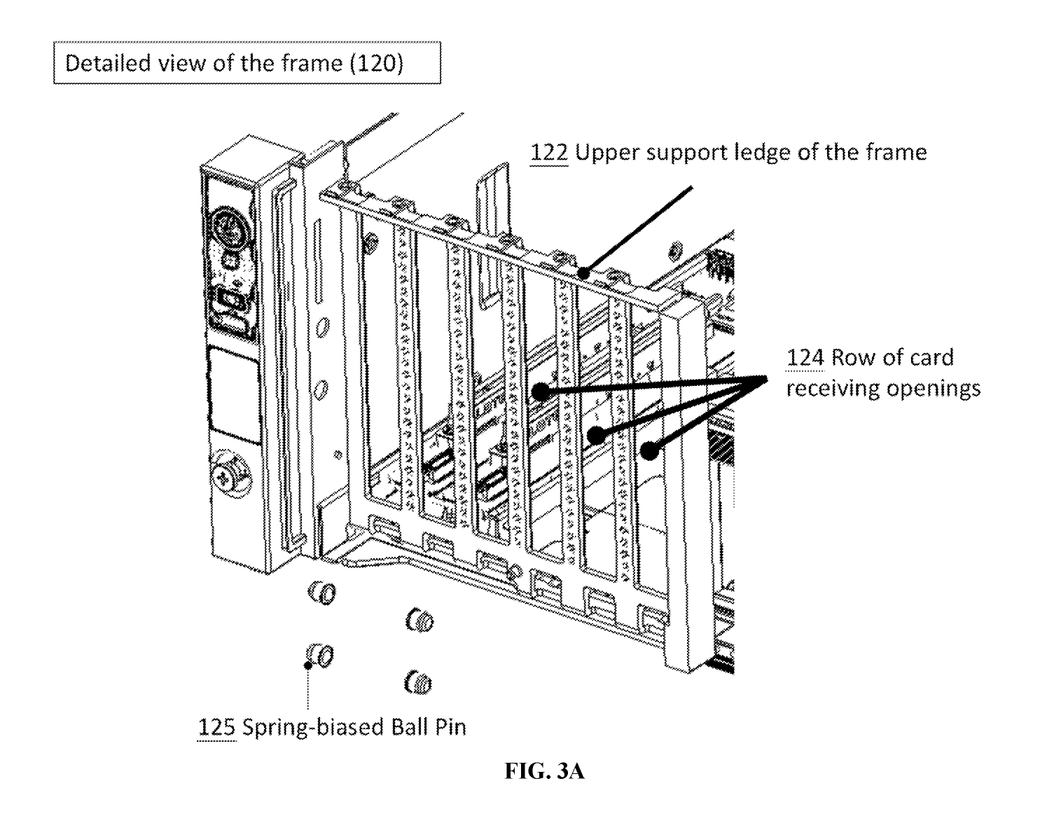

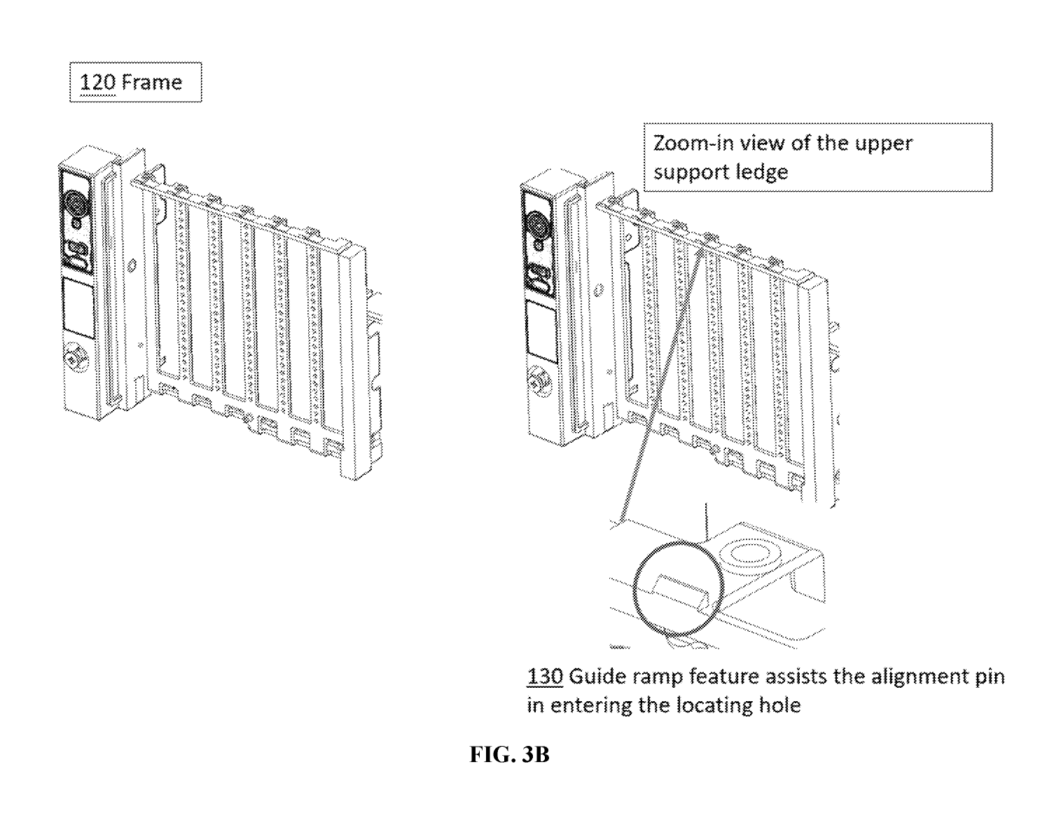

As shown by the exploded views on the right side of FIG. 2, the expansion card clamping apparatus 100 includes a frame 120 and a clamping bracket assembly 160. In some embodiments, the frame 120 is configured to be fixed to the server chassis, for example to a side panel of the chassis by screws or other fastening structures, and defines a row of card receiving openings and an upper support ledge (more details in FIGS. 3A and 3B) that supports bracket portions of the expansion cards in fixed positions relative to the chassis.

In some embodiments, the clamping bracket assembly 160 is coupled to the frame 120 so that the clamping bracket assembly 160 pivots as a unit relative to the frame between an open position and a closed position. When the clamping bracket assembly 160 is pivoted to the open position, the upper support ledge of the frame 120 is exposed, allowing bracket portions of multiple expansion cards to be placed on the upper support ledge and aligned with the card receiving openings. When the clamping bracket assembly 160 is pivoted back to the closed position, a clamping bar of the clamping bracket assembly 160 presses against the bracket portions and simultaneously secures the plurality of expansion cards to the chassis.

FIG. 3A illustrates a detailed view of the frame 120 of the expansion card clamping apparatus 100, in accordance with some embodiments. In some embodiments, the frame 120 is fixed to a front side of the server chassis and defines a row of card receiving openings 124. The card receiving openings 124 are positioned and dimensioned to receive bracket portions of a plurality of expansion cards so that external connectors of the cards can be exposed at the front of the chassis. In some embodiments, the frame 120 further includes an upper support ledge 122 that covers and extends along the row of card receiving openings 124. The upper support ledge 122 forms a continuous support surface on which the bracket portions of the expansion cards rest, thereby positioning the cards in a fixed orientation relative to the chassis.

In some embodiments, the frame 120 further cooperates with one or more spring-biased ball pins 125. Each spring-biased ball pin 125 may be received in a corresponding mounting hole of the server chassis or the frame 120 and includes a spring-loaded ball that protrudes from the mounting hole. In some embodiments, the spring-biased ball pins 125 are arranged so that the protruding balls engage complementary surfaces or recesses of the clamping bracket assembly 160 when the clamping bracket assembly reaches its open and closed positions, thereby providing a detent function that helps to positively locate the clamping bracket assembly and handle in those positions.

FIG. 3B illustrates additional views of the frame 120, in accordance with some embodiments. As shown, the frame 120 includes the upper support ledge 122 that runs along the row of card receiving openings 124 (see FIG. 3A). A zoomed-in view of a portion of the upper support ledge 122 shows a guide ramp feature 130.

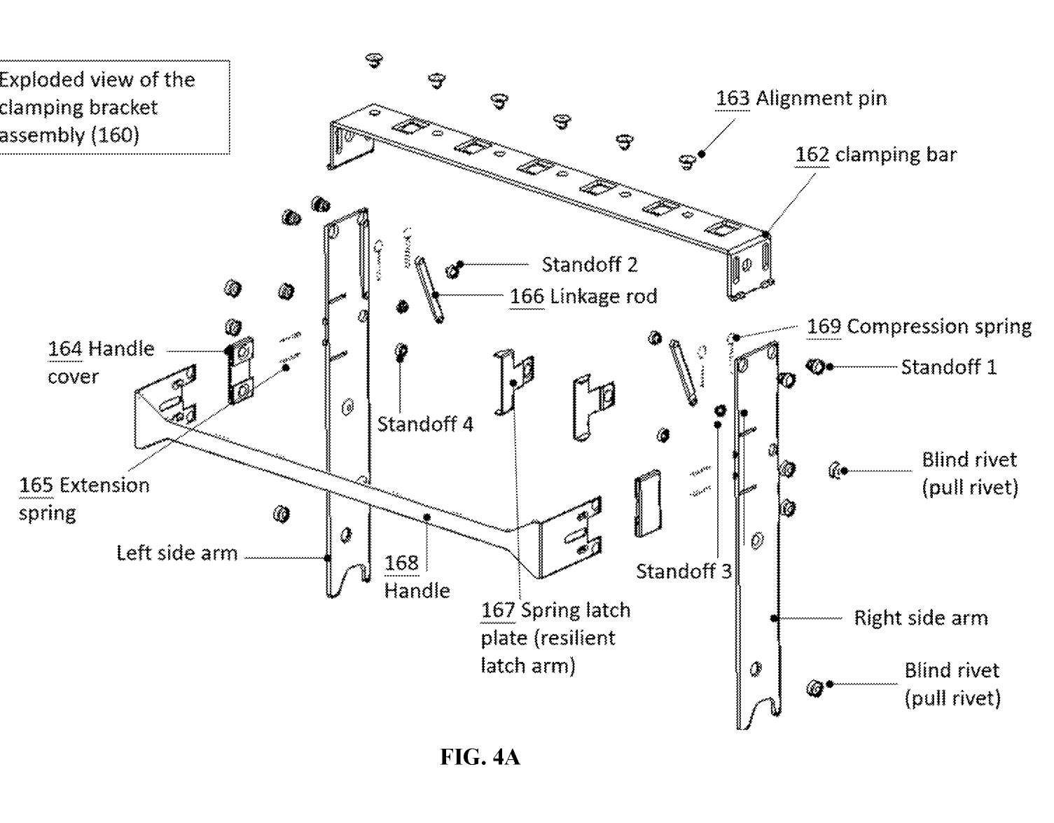

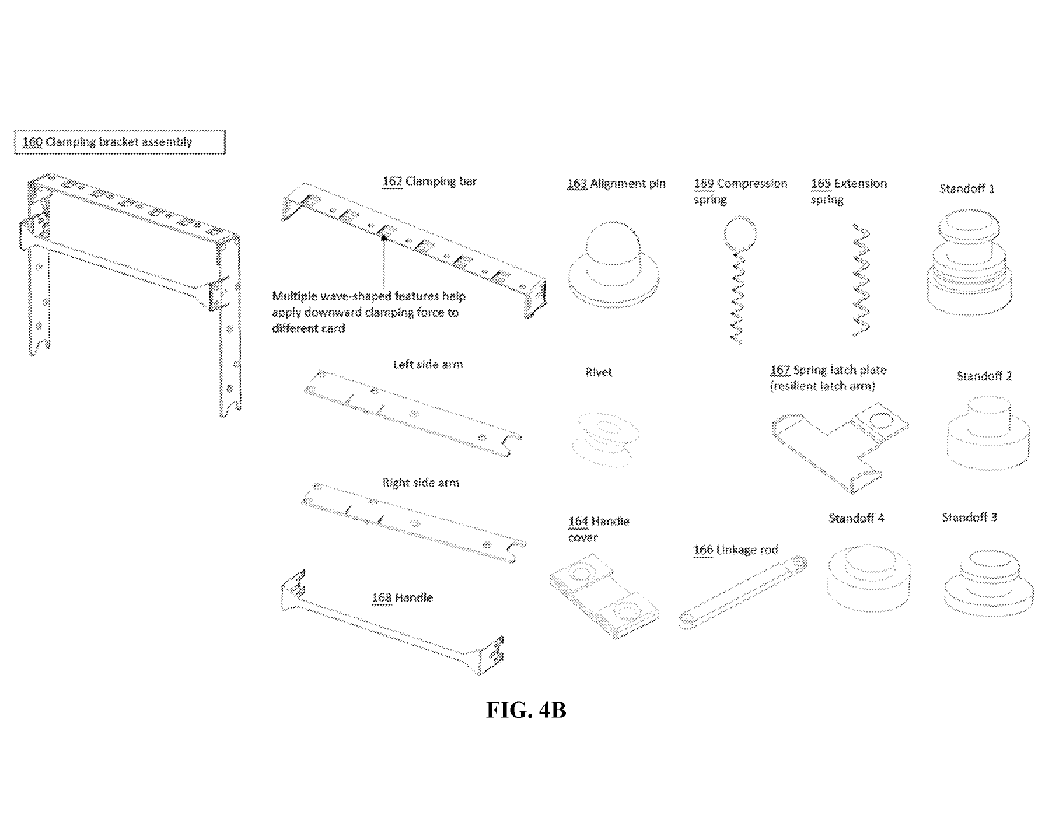

In some embodiments, an alignment pin that is rigidly connected to a clamping bar of the clamping bracket assembly 160 (described in greater detail with reference to FIGS. 4A and 4B) is positioned to contact the guide ramp feature 130 as the clamping bracket assembly pivots from the open position toward the closed position. The guide ramp feature 130 provides an inclined surface that lifts and laterally guides the alignment pin into the locating hole, even when the clamping bracket assembly is slightly misaligned due to manufacturing tolerances or user handling. In some embodiments, the ramp geometry is selected such that, once the alignment pin has ridden over the ramp and dropped into the locating hole, the clamping bracket assembly is accurately positioned in the closed position, thereby helping to ensure that the clamping bar uniformly clamps the bracket portions of the expansion cards against the upper support ledge 122.

Note that the combination of the guide ramp feature 130 on the frame 120 and the alignment pin on the clamping bar of the clamping bracket assembly 160 is merely one example of an alignment and locating structure. In some embodiments, instead of or in addition to the guide ramp feature 130 and the alignment pin, the frame 120 may include one or more side guide slots, and the clamping bracket assembly 160 may include corresponding guide tabs that slide within the guide slots as the clamping bracket assembly pivots, thereby constraining lateral movement and positioning the clamping bar in the closed position. In other embodiments, tapered bosses or chamfered shoulders formed on the clamping bracket assembly 160 may seat in complementary recesses formed in the frame 120 when the clamping bracket assembly reaches the closed position.

The goal of these various alignment structures is to automatically guide the clamping bracket assembly into a repeatable closed position in which the clamping bar accurately overlies the upper support ledge 122 and applies a stable clamping force to bracket portions of the expansion cards, while tolerating manufacturing variations and minimizing the force required from the user during operation.

FIG. 4A illustrates an exploded view of an example clamping bracket assembly 160, in accordance with some embodiments. The clamping bracket assembly 160 includes a clamping bar 162 extending laterally between a left side arm and a right side arm. The clamping bar 162 is positioned, when assembled, to face the upper support ledge 122 of the frame 120 and to overlie bracket portions of a row of expansion cards.

In some embodiments, the clamping bar 162 carries one or more alignment pins 163. In certain implementations, a single alignment pin 163 cooperates with a locating hole to position the clamping bar 162 relative to the upper support ledge 122. In other implementations, two alignment pins 163 are provided near opposite ends of the clamping bar 162. In still other implementations, such as the example shown in FIG. 4A, a plurality of alignment pins 163 are spaced along the clamping bar 162, each alignment pin 163 being receivable in a corresponding opening or recess formed in the frame 120 and/or the chassis at locations generally aligned with respective card receiving openings 124. These multiple alignment pins 163 help distribute clamping forces and maintain alignment of the clamping bar 162 along its length.

In some embodiments, a handle 168 extends between the left and right side arms and is configured to be grasped by a user to move the clamping bracket assembly 160 between the open and closed positions. In some embodiments, a handle cover 164 is mounted on the handle 168 at a region adjacent to one of the side arms.. The handle cover 164 is rigidly coupled to the side arm and provides functional features. In some embodiments, a first end of a linkage rod 166 is pivotally coupled to the handle cover 164 (and in other embodiments the first end of the linkage rod 166 is pivotally coupled directly to the handle 168). The handle cover 164 further carries a latch projection (boss feature, e.g., a bump on the face of the handle cover 164 that will sit underneath the spring latch plate 167 once assembled) configured to cooperate with a spring latch plate 167 mounted on the side arm. The spring latch plate 167 is formed as a metal spring plate and has an engagement edge (for example a bent hook or latching edge at a free end of the spring latch plate 167) that engages with and retains the handle 168 and the handle cover 164 against the corresponding side arm when the clamping bracket assembly 160 is in the closed position, and is elastically deflectable to allow the handle 168 and the handle cover 164 to move away from the side arm when the user pulls the handle. A second end of the linkage rod 166 is coupled to the clamping bar 162. In the closed position, the linkage rod 166 is in a slanted orientation. When the handle 168 is pulled forward or outward by the user, the handle cover 164 draws the first end of the linkage rod 166 forward, causing the linkage rod 166 to rotate toward a more vertical orientation and to push its second end upward. This motion raises the clamping bar 162 by a step in height and disengages the clamping bar 162 from the upper support ledge 122, thereby transitioning the clamping bracket assembly 160 out of the fully closed clamping condition and toward the open position.

In some embodiments, the spring latch plate 167 (resilient latch arm) is mounted to the side arm by standoffs such as Standoff 2 and Standoff 4. The spring latch plate 167 overlies at least part of the handle cover 164 and has a hooked or engagement portion that engages with the frame 120 when the clamping bracket assembly 160 is in the closed position. The boss on the handle cover 164 is positioned so that, as the handle 168 is pulled, the boss pushes against the spring latch plate 167, elastically deflecting it away from the frame 120 and causing the hooked portion to disengage from the frame 120. Thus, pulling the handle 168 both unlatches the clamping bracket assembly 160 from the frame 120 and, via the linkage rod 166, lifts the clamping bar 162. In some embodiments, the spring latch plate 167 (resilient latch arm) is mounted to the frame 120 or to a side arm via standoffs such as Standoff 2 and Standoff 4.

In some embodiments, the expansion card clamping apparatus further includes a clamping biasing member configured to urge the clamping bracket assembly 160 toward the closed position. In the illustrated embodiments, the clamping biasing member includes one or more springs, such as the extension springs 165 and/or the compression springs 169 described herein; however, the clamping biasing member may be implemented in various forms, including a coil spring (e.g., a compression spring), a torsion spring disposed about a pivot, a leaf spring or resilient spring plate, an elastomeric compressible element, a spring washer (e.g., a Belleville washer or wave spring), an integrally formed resilient flexure of the frame 120 or the clamping bracket assembly 160, a magnetic biasing arrangement, or any other resilient or force-applying element configured to provide a biasing force toward the closed position. In some embodiments, a pair of extension springs 165 are provided, each connected between the handle 168 (in some embodiments, the handle cover 164) and a respective one of the left and right side arms. When the handle 168 is pulled outward, the extension springs 165 are stretched and thereby limit the range of the pulling motion and generate a restoring force that biases the handle 168, and thus the clamping bracket assembly 160, back toward the closed position when released. Similarly, in some embodiments, one or more compression springs 169 are provided between the clamping bar 162 and the left and right side arms (for example, via Standoff 1 and Standoff 3). When the linkage rod 166 lifts the clamping bar 162, the compression springs 169 compress and limit the amount of upward travel. When the handle 168 is released, the compression springs 169 exert a downward force on the clamping bar 162, cooperating with the extension springs 165 to return the clamping bracket assembly 160 to its natural closed position and to apply a downward clamping force on the bracket portions of the expansion cards.

Various standoffs (Standoff 1-4) provide mounting points and spacing for the linkage rod 166, the spring latch plate 167, and the springs 165 and 169, and help maintain rigidity of the side arms. Blind rivets (pull rivets) on the side arms are used to secure these components and, in some implementations, may also act as mechanical stops or contact features that provide tactile feedback to the user as the handle 168 is moved between positions.

FIG. 4B illustrates the clamping bracket assembly 160 and its component parts in a more diagrammatic form, in accordance with some embodiments. As shown, the clamping bar 162 extends across the top of the assembly and includes a non-planar contact profile formed by multiple wave-shaped features. In some embodiments, these wave-shaped features are positioned so that, in the closed position, different portions of the clamping bar 162 contact top edges of the bracket portions of extension cards along the upper support ledge of the frame, helping to distribute the downward clamping force and accommodate tolerances between cards. One or more alignment pins 163 project from the clamping bar 162 and are configured to cooperate with the guide ramp feature 130 and corresponding locating holes. A pair of compression springs 169 are shown as separate components that are assembled between the clamping bar 162 and the left and right side arms. In other embodiments, one or more compression springs 169 may be arranged between the clamping bar 162 and the frame 120 or directly between the clamping bar 162 and a structural portion of the chassis, so that the spring force is transmitted through the frame or chassis while still urging the clamping bracket assembly toward the closed position.

The left and right side arms support the handle 168, which spans the front of the clamping bracket assembly 160 (so that the handle 168 is exposed at the front side of the clamping bracket assembly 160 for a user to grasp). A handle cover 164 is shown as a separate part that attaches to the handle 168 and receives one end of the linkage rod 166. The other end of the linkage rod 166 is coupled to the clamping bar 162. In the closed position, the linkage rod 166 is inclined; when the handle 168 is pulled, the handle cover 164 drives the first end of the linkage rod 166 forward so that the linkage rod 166 rotates toward a more upright orientation and pushes its second end upward, thereby lifting the clamping bar 162 and temporarily enlarging the opening between the clamping bar 162 and the frame 120 to facilitate insertion or removal of the expansion cards. The spring latch plate 167 (resilient latch arm) and standoffs 1-4 are depicted as discrete pieces that mount to one of the side arms and provide spacing and engagement geometry for the latch and springs. Extension springs 165 are shown as separate components that connect between the handle 168 and the side arms. Rivets and other small fasteners are used to join these parts together. In other embodiments, some of the parts shown in FIG. 4B may be formed integrally (for example, the side arms and handle may be formed as a single bent metal piece), or different fastening techniques may be used while preserving the overall function of the clamping bracket assembly 160.

In some embodiments, the length of the clamping bar 162 and the length of the upper support ledge 122 are selected based on the number of card receiving openings 124 along the frame 120. For example, different versions of the frame 120 and clamping bracket assembly 160 may be provided with different lengths so as to secure different numbers of expansion cards (for instance, four-slot, six-slot, or eight-slot configurations), while preserving the same clamping mechanism.

In some embodiments, the frame 120 is elongated and configured to receive a plurality of clamping bracket assemblies 160 spaced along the row of card receiving openings 124. Each clamping bracket assembly 160 may span a subset of the card receiving openings 124 to define an independently operable clamping zone. A user can open one clamping bracket assembly 160 to install or remove cards in a corresponding zone while leaving other zones clamped.

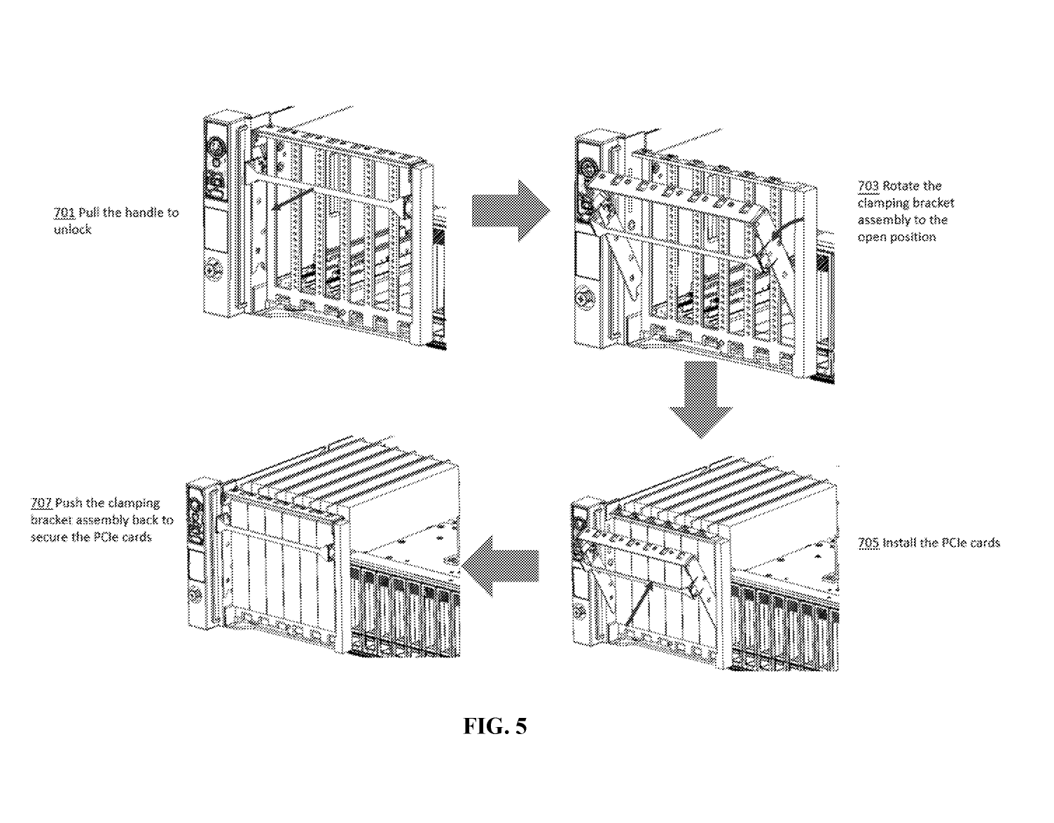

FIG. 5 illustrates an example sequence of user operations for pulling a handle to unlock, rotating the clamping bracket assembly to an open position, installing PCIe cards, and pushing the clamping bracket assembly back to secure the PCIe cards, in accordance with some embodiments.

In the upper-left view, the clamping bracket assembly 160 is in a closed position in which a clamping bar 162 overlies an upper support ledge 122 of the frame 120. In this condition, the clamping bar 162 simultaneously presses bracket portions of a plurality of expansion cards (e.g., PCIe cards) against the upper support ledge 122 so as to secure the cards in the chassis. A latch structure, formed for example by a spring latch plate 167 (resilient latch arm) on the frame 120 and a latch projection on a handle 168 or handle cover 164 of the clamping bracket assembly 160, releasably retains the clamping bracket assembly 160 in the closed position, and one or more springs bias the clamping bracket assembly 160 toward the closed position as described elsewhere herein.

In the first step 701, a user manually grasps the handle 168 and pulls the handle forward or outward to unlock the clamping bracket assembly 160. Pulling the handle 168 causes the latch projection on the handle/handle cover to deflect the resilient spring latch plate 167 and disengage from an engagement edge of the spring latch plate, thereby releasing the latch structure and allowing the clamping bracket assembly 160 to move away from the frame 120 without the use of tools. At the same time, the linkage rod 166 and associated springs (e.g., extension springs 165 and compression springs 169) begin to raise the clamping bar 162 relative to the upper support ledge 122, partially relieving the clamping force on the bracket portions of the expansion cards.

In the second step 703, the user rotates the clamping bracket assembly 160 as a unit about pivot connections at rear ends of its side arms, thereby pivoting the clamping bracket assembly 160 relative to the frame 120 to an open position. As the clamping bracket assembly 160 pivots, the clamping bar 162 moves away from the upper support ledge 122 to create an enlarged opening in front of the row of card receiving openings 124. In this open position, the clamping bar 162 no longer obstructs the bracket portions of the expansion card positions, and the user has unobstructed access to the card receiving openings 124 defined by the frame 120.

In the third step 705, with the clamping bracket assembly 160 held in the open position, the user installs or removes expansion cards. For example, a plurality of PCIe cards may be inserted so that edge connectors of the cards engage corresponding sockets on the motherboard and bracket portions of the cards are seated on the upper support ledge 122 and aligned with the row of card receiving openings 124. Because the clamping bar 162 is pivoted away from the upper support ledge 122, the user can insert or remove multiple cards without loosening or tightening individual screws, and can do so even in a relatively confined space at the front of the chassis.

In the fourth step 707, after the desired expansion cards have been installed, the user pushes the clamping bracket assembly 160 back toward the frame 120. The clamping bracket assembly 160 pivots as a unit from the open position toward the closed position. As the clamping bracket assembly 160 approaches the closed position, the clamping bar 162 moves downward toward the upper support ledge 122 and again overlies the bracket portions of the installed expansion cards. In the embodiments including alignment pins 163 and a guide ramp feature 130, alignment pins 163 rigidly connected to the clamping bar 162 ride along the guide ramp feature 130 and drop into corresponding locating holes in the chassis or the frame 120 as the clamping bracket assembly 160 reaches the closed position, thereby aligning and stabilizing the clamping bar 162. Compression springs 169 arranged between the clamping bar 162 and the side arms urge the clamping bar 162 downward to apply a clamping force, while extension springs 165 coupled to the handle 168 bias the handle 168 toward the position corresponding to the closed position. In some embodiments, spring-biased ball pins 125 on the frame 120 provide a detent that produces tactile feedback when the clamping bracket assembly 160 snaps into the closed position. When fully closed, the latch projection on the handle/handle cover again engages the resilient spring latch plate 167, retaining the clamping bracket assembly 160 in the closed position in which the clamping bar 162 simultaneously clamps the bracket portions of the plurality of expansion cards against the upper support ledge 122 and secures the cards to the chassis.

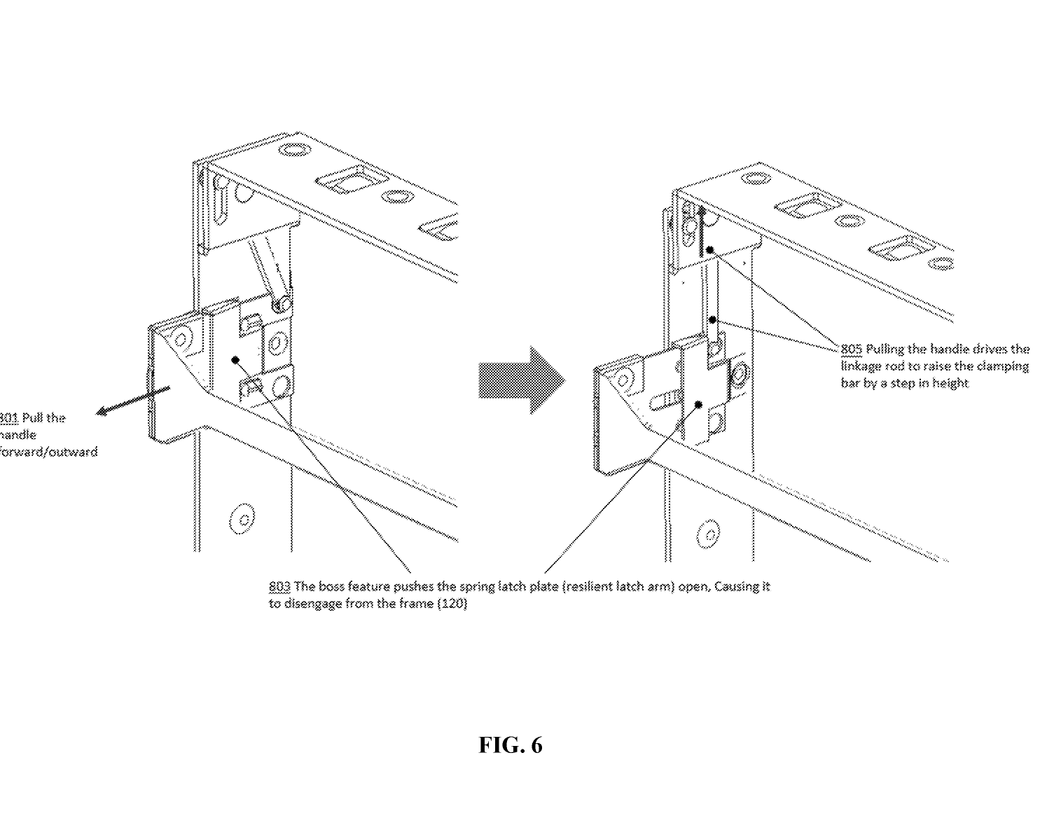

FIG. 6 illustrates an example unlocking operation, in accordance with some embodiments. In the left view, the clamping bracket assembly 160 is in the closed position and a user begins the unlocking operation by pulling the handle 168 forward or outward, as indicated by arrow 801. The handle 168 and handle cover 164 move together away from the corresponding side arm. A boss feature formed on the handle cover 164 bears against the spring latch plate 167 (resilient latch arm). As the handle 168 is pulled, the boss pushes against the spring latch plate 167, as indicated at 803, elastically deflecting the spring latch plate 167 so that its hooked engagement portion disengages from the frame 120. This action releases the latch structure that had been retaining the clamping bracket assembly 160 in the closed position.

In the right view of FIG. 6, continued pulling of the handle 168 causes further motion of the handle cover 164 and the first end of the linkage rod 166. Because the linkage rod 166 is pivotally coupled at its first end to the handle cover 164 and at its second end to the clamping bar 162, the forward motion of the first end of the linkage rod 166 causes the linkage rod 166 to rotate toward a more vertical orientation and to push its second end upward. As indicated at 805, this motion raises the clamping bar 162 by a step in height relative to the upper support ledge 122 of the frame 120, thereby reducing or removing the clamping force on the bracket portions of the expansion cards and preparing the clamping bracket assembly 160 to be pivoted away from the frame 120 to the open position. Extension springs 165 and compression springs 169 (not separately labeled in FIG. 6) stretch and compress during this operation so that, when the handle 168 is later released, the clamping bracket assembly 160 is biased back toward the closed, latched condition.

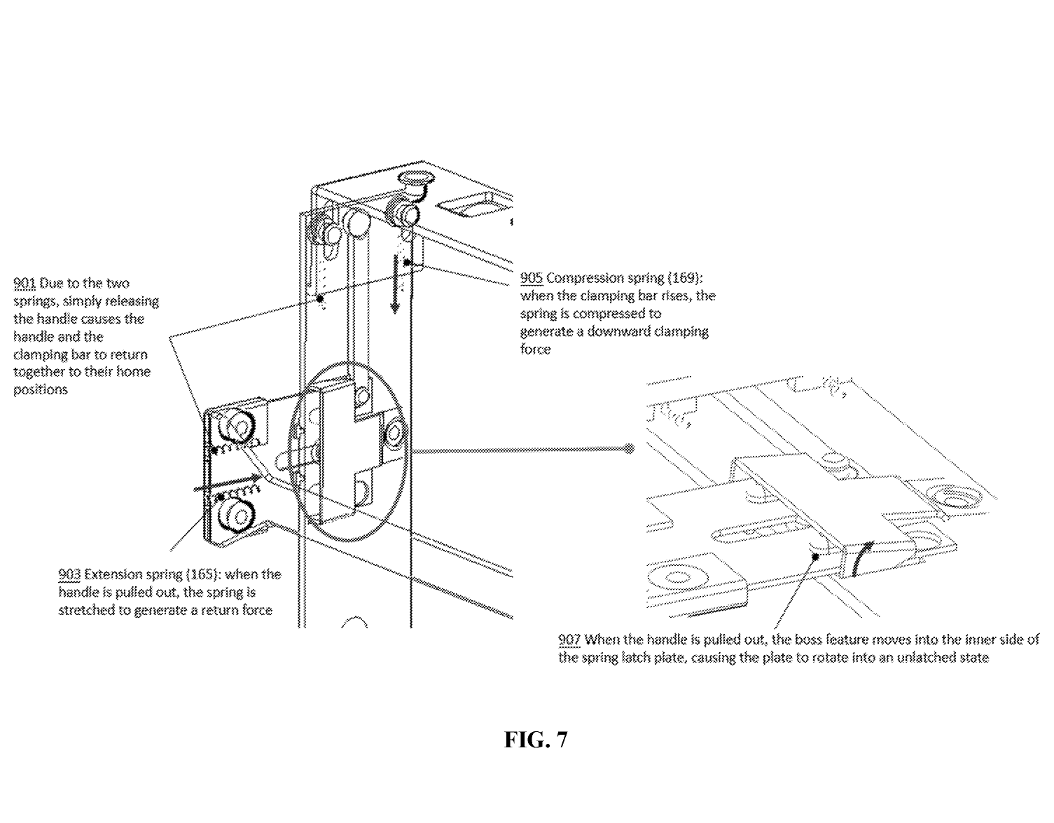

FIG. 7 illustrates an example interaction of an extension spring and a compression spring that causes the handle and clamping bar to return to their home positions and generates a downward clamping force, in accordance with some embodiments. In the left view, the clamping bracket assembly 160 is shown in a partially open state after the user has pulled the handle 168 forward. An extension spring 165 is connected between the handle 168 and a side arm, and a compression spring 169 is arranged between the clamping bar 162 and the side arm. As indicated at 903, pulling the handle 168 stretches the extension spring 165 to generate a return force tending to pull the handle 168 back toward the closed position. As indicated at 905, raising the clamping bar 162 compresses the compression spring 169 so that the compression spring 169 stores energy for generating a downward clamping force.

In some embodiments, when the user releases the handle 168, the combined action of the extension spring 165 and the compression spring 169 automatically returns both the handle 168 and the clamping bar 162 to their home positions, as indicated at 901. The extension spring 165 pulls the handle 168 and handle cover 164 back toward the frame 120, while the compression spring 169 pushes the clamping bar 162 downward toward the upper support ledge 122. In the zoomed-in view on the right, a boss feature on the handle cover 164 is shown at 907 on the inner side of the spring latch plate 167. When the handle 168 is pulled out, the boss moves into this inner region and causes the spring latch plate 167 to rotate into an unlatched state; when the handle 168 is released and returns, the spring latch plate 167 elastically returns and re-engages the boss to latch the clamping bracket assembly 160 in the closed position, with the compression spring 169 applying the desired downward clamping force on the expansion cards.

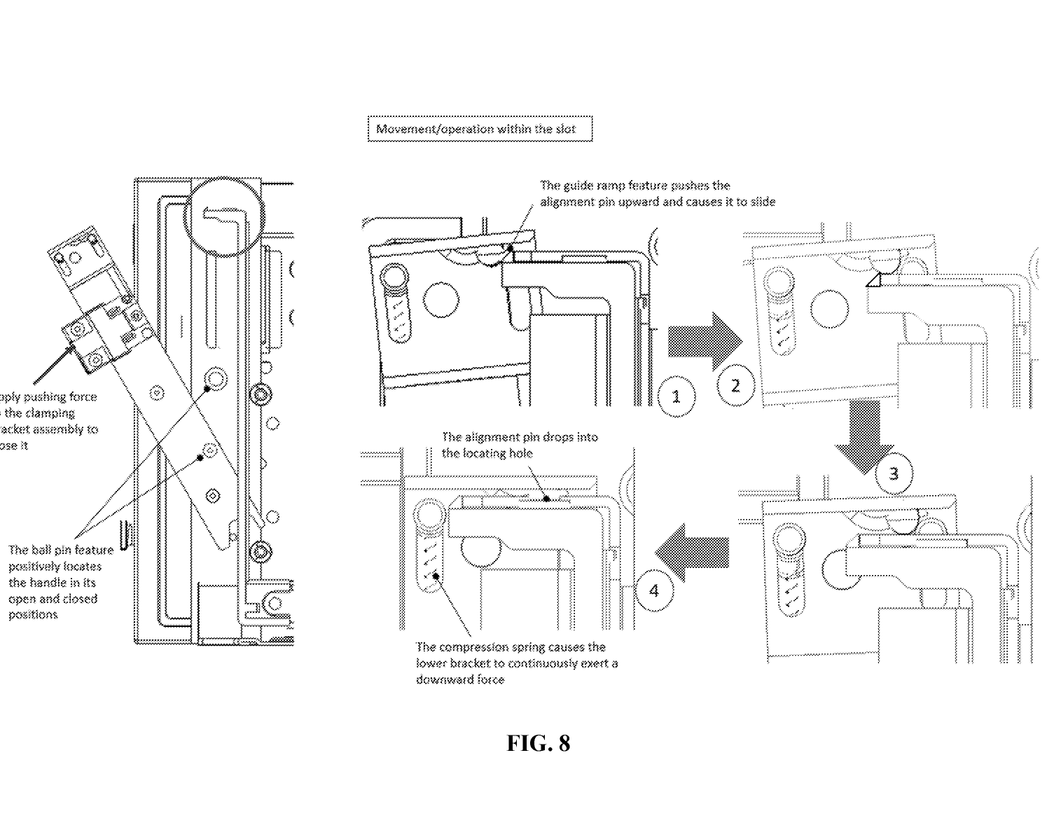

FIG. 8 illustrates example movement of the clamping bracket assembly 160 within a side slot of the chassis as the assembly is pushed from the open position back to the closed position, in accordance with some embodiments. In the left view, the clamping bracket assembly 160 is shown in an open, rotated position. A user applies a pushing force to the clamping bracket assembly 160 to close it. As the assembly pivots toward the frame 120, a spring-biased ball pin (such as ball pin 125 mounted on the frame 120) engages corresponding recesses so as to positively locate the handle 168 in its open and closed positions and provide tactile feedback during the closing motion.

The sequence of views on the right side of FIG. 8 shows the movement of the clamping bar 162 and an alignment pin 163 within the slot as the assembly approaches the closed position. In step (1), the alignment pin 163 approaches a guide ramp feature 130 formed adjacent to a locating hole in the chassis or frame 120. In step (2), continued pushing of the clamping bracket assembly 160 causes the guide ramp feature 130 to push the alignment pin 163 upward and sideways so that the pin slides along the ramp. In step (3), once the alignment pin 163 has passed the high point of the guide ramp feature 130, the alignment pin 163 drops into the locating hole, as shown in step (4). A compression spring 169 acting between the clamping bar 162 and the side arm urges the clamping bar 162 downward throughout this motion so that, when the alignment pin 163 is seated in the locating hole, the clamping bar 162 is pressed firmly against the upper support ledge 122 to exert a continuous downward clamping force on the bracket portions of the installed expansion cards. In this way, cooperation of the guide ramp feature 130, alignment pin 163, locating hole, compression spring 169, and ball pin 125 positively guides and stabilizes the clamping bracket assembly 160 as it moves within the slot and reaches its fully closed, clamped position.

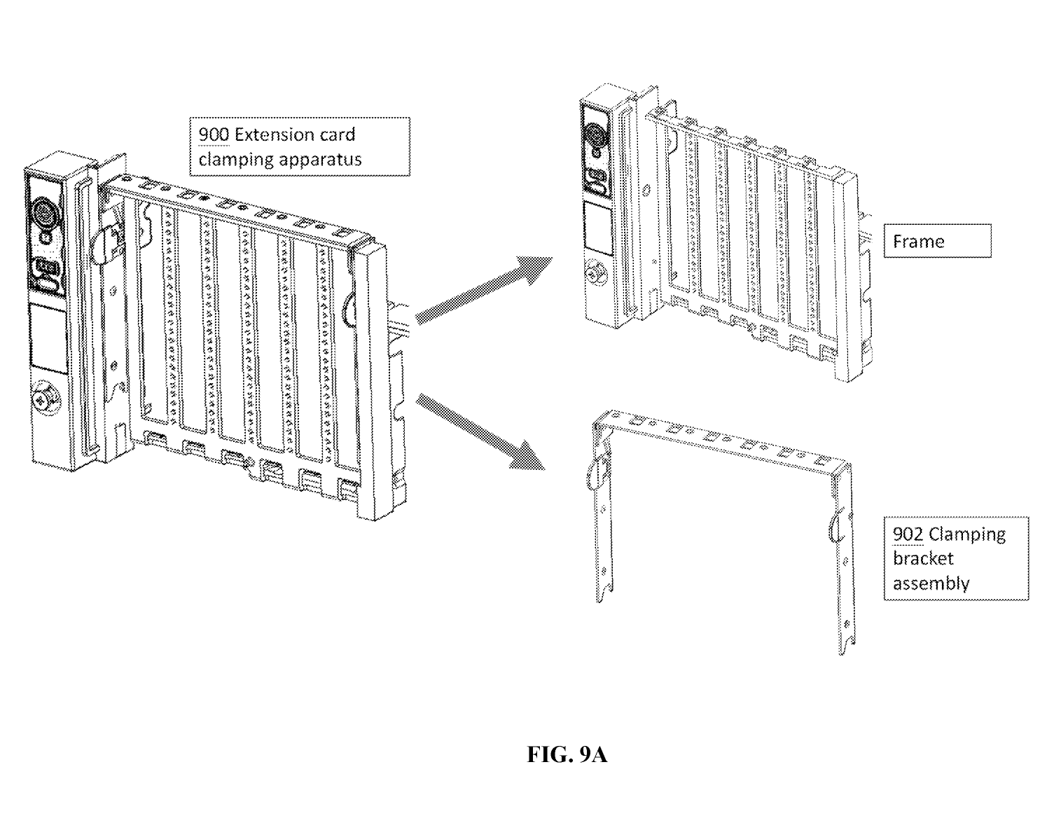

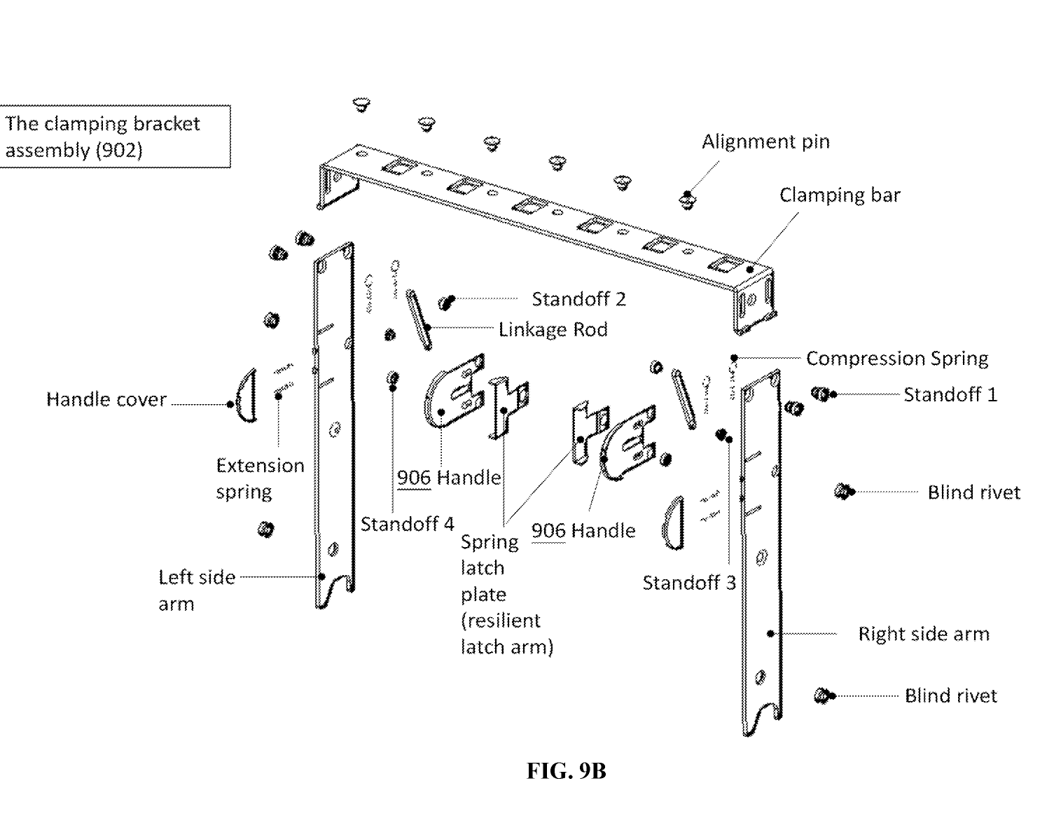

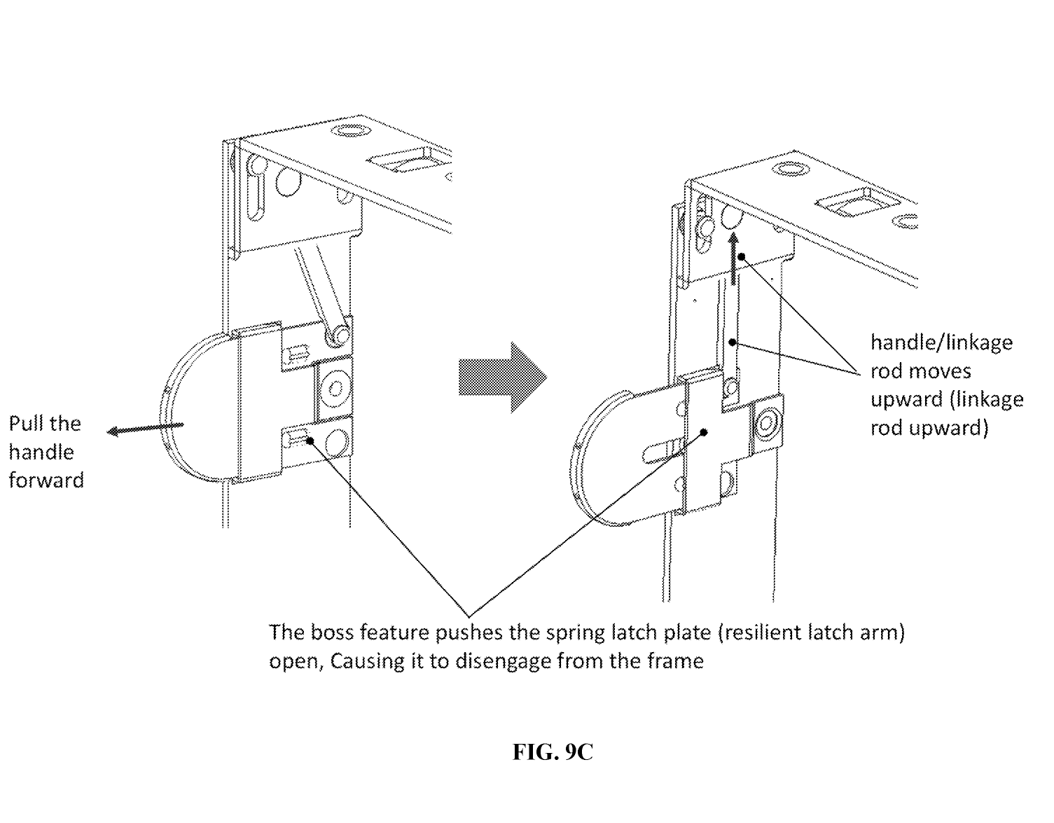

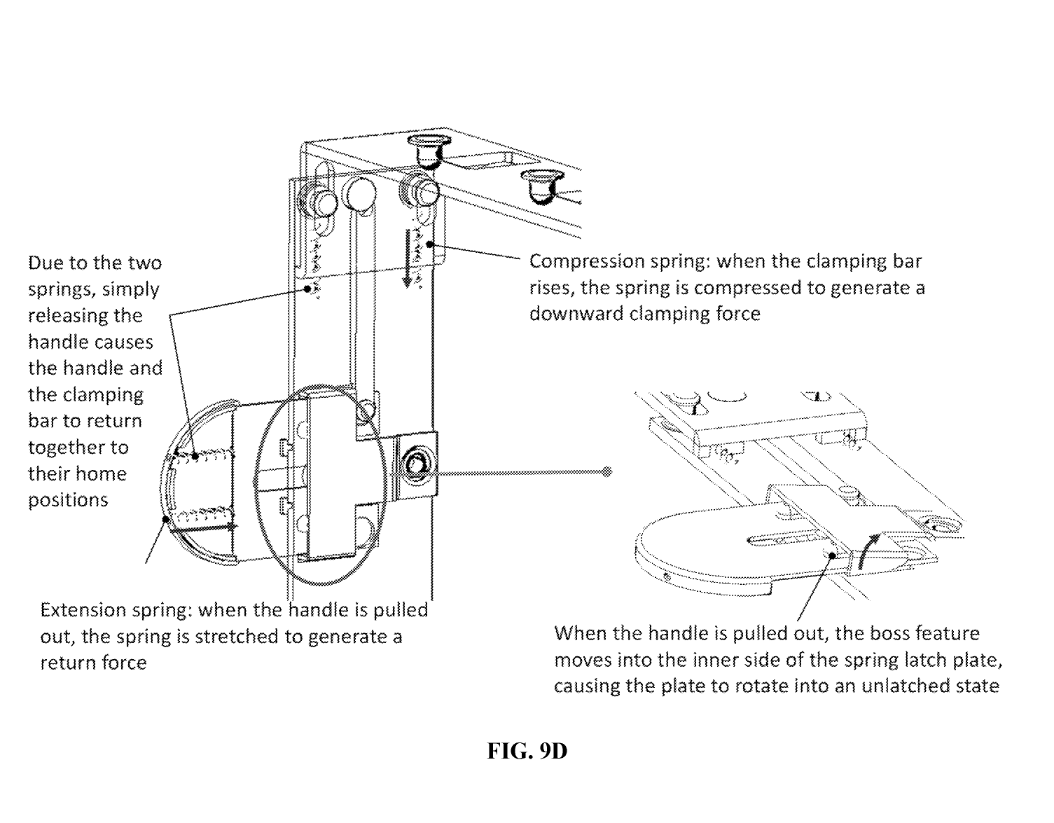

FIG. 9A-9D illustrate another embodiment of the expansion card clamping apparatus, in accordance with some embodiments.

The expansion card clamping apparatus 900 illustrated in FIG. 9A corresponds generally to the expansion card clamping apparatus described above with reference to FIG. 2, but differs at least in that the clamping bracket assembly 902 includes a different handle arrangement for actuating the clamping and unlatching functions. In particular, instead of a handle spanning the side of the apparatus (e.g., cross-bar handle 168 of FIG. 4A), the clamping bracket assembly 902 of FIG. 9A includes a pair of side-mounted handles (see handles 906 of FIG. 9B) disposed on opposite sides of the clamping bracket assembly 902. The apparatus 900 is shown to illustrate that various components, including the handle and associated latch/actuation features, may be implemented in alternative forms while maintaining the overall clamping function.

FIG. 9B is an exploded view of the clamping bracket assembly 902. The clamping bracket assembly 902 generally corresponds to the clamping bracket assembly described above with reference to FIG. 4A, except that the handle structure is implemented in a different form. In particular, instead of a cross-bar handle spanning a side (e.g., front side) of the clamping bracket assembly, the embodiment of FIG. 9B includes a pair of handles 906 disposed on opposite sides of the clamping bracket assembly 902, for example on the left and right side arms. In some embodiments, each handle 906 is configured as a laterally projecting pull member having a rounded outer profile. The handles 906 are operatively coupled to the linkage rod such that pulling the handles 906 causes the linkage rod to move and thereby lift the clamping bar. Further, in some embodiments, each handle 906 includes or carries a boss feature that interacts with the spring latch plate (resilient latch arm) such that pulling the handles 906 elastically deflects the spring latch plate to disengage the clamping bracket assembly 902 from the frame.

FIG. 9C illustrates operation of the handle/latch interface for the embodiment of FIGS. 9A-9B. In some embodiments, unlocking the clamping bracket assembly 902 from the frame is performed by pulling the handles 906 forward (outward) on both sides of the clamping bracket assembly 902 (e.g., pulling the two handles 906 substantially simultaneously). When the handles 906 are pulled, a boss feature associated with each handle 906 (for example, a boss on the handle cover 904 and/or on the handle 906) pushes against the spring latch plate (resilient latch arm), elastically deflecting the spring latch plate away from the frame and thereby disengaging the spring latch plate from the frame. In addition, the handle motion drives the linkage rod upward, thereby lifting the clamping bar to release the clamped expansion cards, in a manner generally corresponding to the operation described above with reference to FIG. 6, but implemented using the pair of side-mounted handles 906 rather than a cross-bar handle.

FIG. 9D further illustrates the restoring/clamping action of the biasing elements in the embodiment of FIGS. 9A-9C. In some embodiments, an extension spring is coupled between each handle 906 (and/or the handle cover 904) and a corresponding side arm such that pulling the handles 906 stretches the extension spring and generates a restoring force. In some embodiments, one or more compression springs are provided between the clamping bar and at least one structural component of the clamping bracket assembly 902 (for example, the side arms via standoffs), such that when the clamping bar rises, the compression spring(s) compress and subsequently exert a downward force on the clamping bar to provide a downward clamping force when the clamping bracket assembly 902 returns toward its closed position. Accordingly, in the embodiment of FIG. 9D, simply releasing the pair of handles 906 allows the restoring forces of the extension spring(s) and compression spring(s) to return the handles 906 and the clamping bar toward their home positions, thereby returning the clamping bracket assembly 902 toward the closed, clamping state, in a manner generally corresponding to FIG. 7 but using the pair of side- mounted handles 906.

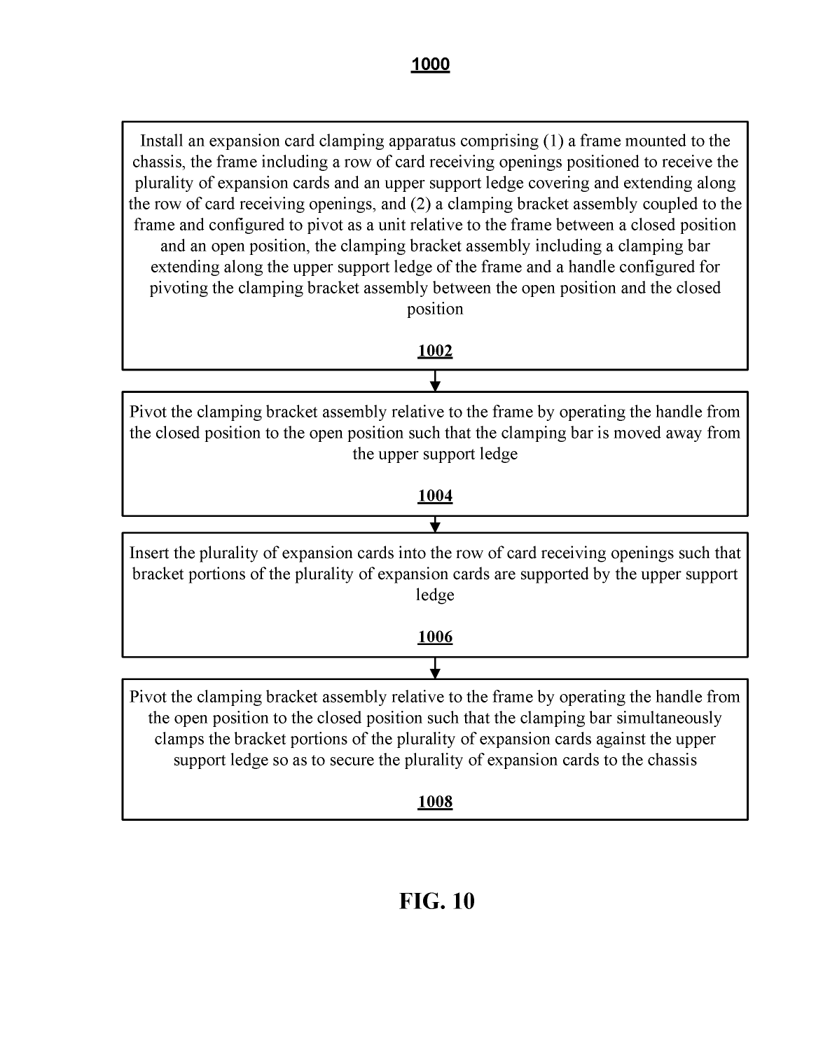

FIG. 10 is a flowchart of an example process 1000. In some implementations, one or more process blocks of FIG. 10 may be performed by a device, by an operator, or by an operator using a device.

As shown in FIG. 10, process 1000 may include installing an expansion card clamping apparatus having (1) a frame mounted to the chassis, the frame including a row of card receiving openings positioned to receive the plurality of expansion cards and an upper support ledge covering and extending along the row of card receiving openings, and (2) a clamping bracket assembly coupled to the frame and configured to pivot as a unit relative to the frame between a closed position and an open position, the clamping bracket assembly including a clamping bar extending along the upper support ledge of the frame and a handle configured for pivoting the clamping bracket assembly between the open position and the closed position (block 1002). For example, the device or the operator may install an expansion card clamping apparatus having the frame and clamping bracket assembly configured as described above.

As also shown in FIG. 10, process 1000 may include pivoting the clamping bracket assembly relative to the frame by operating the handle from the closed position to the open position such that the clamping bar is moved away from the upper support ledge (block 1004). For example, the device or the operator may pivot the clamping bracket assembly relative to the frame by operating the handle from the closed position to the open position such that the clamping bar is moved away from the upper support ledge, as described above. As further shown in FIG. 10, process 1000 may include inserting the plurality of expansion cards into the row of card receiving openings such that bracket portions of the plurality of expansion cards are supported by the upper support ledge (block 1006). For example, the device or the operator may insert the plurality of expansion cards into the row of card receiving openings such that bracket portions of the plurality of expansion cards are supported by the upper support ledge, as described above.

As also shown in FIG. 10, process 1000 may include pivoting the clamping bracket assembly relative to the frame by operating the handle from the open position to the closed position such that the clamping bar simultaneously clamps the bracket portions of the plurality of expansion cards against the upper support ledge so as to secure the plurality of expansion cards to the chassis (block 1008). For example, the device or the operator may pivot the clamping bracket assembly relative to the frame by operating the handle from the open position to the closed position such that the clamping bar simultaneously clamps the bracket portions of the plurality of expansion cards against the upper support ledge so as to secure the plurality of expansion cards to the chassis, as described above.

Process 1000 may include additional implementations, such as any single implementation or any combination of implementations described below and/or in connection with one or more other processes described elsewhere herein. In a first implementation, pivoting the clamping bracket assembly from the open position to the closed position may further include engaging a latch structure having a first latch portion on the frame and a second latch portion on the clamping bracket assembly so as to releasably retain the clamping bracket assembly in the closed position. In a second implementation, alone or in combination with the first implementation, operating the handle to pivot the clamping bracket assembly between the open position and the closed position may include manually grasping and moving the handle without use of a separate tool.

Although FIG. 10 shows example blocks of process 1000, in some implementations process 1000 may include additional blocks, fewer blocks, different blocks, or differently arranged blocks than those depicted in FIG. 10. Additionally, or alternatively, two or more of the blocks of process 1000 may be performed in parallel.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. This description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, "or" is inclusive and not exclusive, unless expressly indicated otherwise or indicated otherwise by context. Therefore, herein, "A, B, or C" means "A, B, C, A and B, A and C, B and C, or A, B, and C," unless expressly indicated otherwise or indicated otherwise by context. Moreover, "and" is both joint and several, unless expressly indicated otherwise or indicated otherwise by context. Therefore, herein, "A and B" means "A and B, jointly or severally," unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term "include" or "comprise" is used to indicate the existence of the subsequently declared features, but it does not exclude the addition of other features. Conditional language, such as, among others, "can," "could," "might," or "may," unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. An expansion card clamping apparatus for securing one or more expansion cards to a chassis, comprising:
a frame, comprising one or more card receiving openings positioned to receive the one or more expansion cards, and an upper support ledge covering and extending along the one or more card receiving openings and configured to support bracket portions of the one or more expansion cards in a fixed position relative to the chassis; and
a clamping bracket assembly coupled to the frame and configured to pivot as a unit relative to the frame between a closed position and an open position,
wherein the clamping bracket assembly comprises a clamping bar extending along the upper support ledge of the frame and positioned to overlie the bracket portions of the one or more expansion cards, and a handle configured for pivoting the clamping bracket assembly between the open position and the closed position;
wherein, when the clamping bracket assembly is in the open position, the one or more expansion cards are insertable into or removable from the one or more card receiving openings, and
wherein, when the clamping bracket assembly is in the closed position, the clamping bar simultaneously clamps the bracket portions of the one or more expansion cards against the upper support ledge so as to secure the one or more expansion cards to the chassis.

2. The expansion card clamping apparatus of claim 1, further comprising a latch structure having a first latch portion on the frame and a second latch portion on the clamping bracket assembly, the latch structure being configured to releasably retain the clamping bracket assembly in the closed position.

3. The expansion card clamping apparatus of claim 2, wherein the first latch portion comprises a resilient latch arm mounted on the frame and the second latch portion comprises a latch projection formed on the handle.

4. The expansion card clamping apparatus of claim 3, wherein the resilient latch arm comprises a metal spring plate having an engagement edge, and the latch projection is configured to deflect the metal spring plate as the handle moves between the open position and the closed position and to engage the engagement edge when the clamping bracket assembly is in the closed position.

5. The expansion card clamping apparatus of claim 1, further comprising a detent structure comprising a ball and a spring arranged on the frame and configured to provide tactile feedback when the clamping bracket assembly reaches the closed position.

6. The expansion card clamping apparatus of claim 1, further comprising a clamping biasing member configured to urge the clamping bracket assembly toward the closed position.

7. The expansion card clamping apparatus of claim 6, wherein the clamping biasing member comprises a compression spring arranged between the clamping bar and at least one of the frame and the chassis.

8. The expansion card clamping apparatus of claim 1, further comprising an extension spring coupled to the handle and configured to bias the handle toward a position corresponding to the closed position of the clamping bracket assembly.

9. The expansion card clamping apparatus of claim 1, wherein the clamping bracket assembly comprises a pair of side arms extending from opposite ends of the clamping bar, and the clamping bracket assembly is pivotably coupled to the frame.

10. The expansion card clamping apparatus of claim 1, wherein the clamping bar has a non-planar contact profile comprising a plurality of alternating raised and recessed portions configured to contact top edges of the bracket portions at a plurality of spaced locations along the one or more card receiving openings.

11. The expansion card clamping apparatus of claim 1, wherein the frame is configured to be fixed to a side of the chassis.

12. The expansion card clamping apparatus of claim 1, further comprising an alignment pin connected to the clamping bracket assembly and a locating hole formed in the chassis or the frame, wherein the alignment pin enters the locating hole when the clamping bracket assembly is in the closed position.

13. The expansion card clamping apparatus of claim 12, wherein a guide ramp feature is formed adjacent to the locating hole and the alignment pin is configured to ride along the guide ramp as the clamping bracket assembly pivots from the open position toward the closed position.

14. The expansion card clamping apparatus of claim 1, wherein the handle is configured to be manually grasped and operated by a user to move the clamping bracket assembly between the open position and the closed position without use of a separate tool.

15. The expansion card clamping apparatus of claim 1, wherein the one or more expansion cards comprise Peripheral Component Interconnect Express (PCIe) cards and the clamping bar is dimensioned to span bracket portions of at least two of the PCIe cards.

16. The expansion card clamping apparatus of claim 15, wherein a length of the clamping bar and a length of the upper support ledge are selected based on a number of the one or more card receiving openings, such that the expansion card clamping apparatus is configurable to secure different numbers of expansion cards by changing the lengths of the clamping bar and the upper support ledge.

17. The expansion card clamping apparatus of claim 1, wherein the frame is configured to receive a plurality of clamping bracket assemblies spaced along the one or more card receiving openings to form a plurality of independently operable clamping zones.

18. A method of securing one or more expansion cards to a chassis, comprising:
installing an expansion card clamping apparatus comprising (1) a frame comprising one or more card receiving openings positioned to receive the one or more expansion cards and an upper support ledge covering and extending along the one or more card receiving openings, and (2) a clamping bracket assembly coupled to the frame and configured to pivot as a unit relative to the frame between a closed position and an open position, the clamping bracket assembly comprising a clamping bar extending along the upper support ledge of the frame and a handle configured for pivoting the clamping bracket assembly between the open position and the closed position;
pivoting the clamping bracket assembly relative to the frame by operating the handle from the closed position to the open position such that the clamping bar is moved away from the upper support ledge;
inserting the one or more expansion cards into the one or more card receiving openings such that bracket portions of the one or more expansion cards are supported by the upper support ledge; and
pivoting the clamping bracket assembly relative to the frame by operating the handle from the open position to the closed position such that the clamping bar simultaneously clamps the bracket portions of the one or more expansion cards against the upper support ledge so as to secure the one or more expansion cards to the chassis.

19. The method of claim 18, wherein pivoting the clamping bracket assembly from the open position to the closed position further comprises engaging a latch structure having a first latch portion on the frame and a second latch portion on the clamping bracket assembly so as to releasably retain the clamping bracket assembly in the closed position.

20. The method of claim 18, wherein operating the handle to pivot the clamping bracket assembly between the open position and the closed position comprises manually grasping and moving the handle without use of a separate tool.
